(19) United States
(12) Patent Application Publication
(10) Pub. No.: US 2023/0337509 A1
(43) Pub. Date: Oct. 19, 2023

(54) DISPLAY DEVICE

(71) Applicant: Samsung Display Co., Ltd., Yongin-si (KR)

(72) Inventors: SANGWON LEE, Yongin-si (KR); YOUNG-MIN PARK, Yongin-si (KR)

(73) Assignee: Samsung Display Co., Ltd., Yongin-si (KR)

(21) Appl. No.: 18/124,076

(22) Filed: Mar. 21, 2023

(30) Foreign Application Priority Data
Apr. 19, 2022 (KR) 10-2022-0047986

(51) Int. Cl. H10K 59/80; H10K 59/65

(52) U.S. Cl. CPC H10K 59/8792; H10K 59/879; H10K 59/878; H10K 59/65

(57) ABSTRACT

A display device may include a window including a top surface, a bottom portion facing the top surface, and a side portion connecting the top surface to the bottom portion and the window including a transmission region and a light-blocking region, a light-blocking layer disposed below the window and overlapping the light-blocking region in a plan view, a light source spaced apart from the bottom portion in a direction in a plan view, and a display panel disposed below the window. The display panel may include a light sensing device, and may include a display region overlapping the transmission region.

### CROSS-REFERENCE TO RELATED APPLICATIONS

This U.S. non-provisional patent application claims priority to and benefits of Korean Patent Application No. 10-2022-0047986 under 35 U.S.C. § 119, filed on Apr. 19, 2022, in the Korean Intellectual Property Office (KIPO), the entire contents of which are incorporated herein by reference.

### BACKGROUND

The disclosure relates to a display device configured to recognize biometric information.

A display device enables communication between a user and an electronic device by providing various functions of displaying image information to a user or sensing an input from the user. In addition, recent display devices are configured to detect user's biometric data. There are various biometric data recognition methods, such as a capacitance method of sensing a change in electrostatic capacitance between electrodes, an optical method of sensing an incident light using an optical sensor, and an ultrasonic method of sensing vibration using a piezo-electric device.

### SUMMARY

An embodiment of the disclosure provides a display device, which is configured to have an improved biometric data recognition function and high light receiving efficiency.

According to an embodiment of the disclosure, a display device may include a window including a top surface, a bottom portion facing the top surface, and a side portion connecting the top surface to the bottom portion and the window including a transmission region and a light-blocking region, a light-blocking layer disposed below the window and overlapping the light-blocking region in a plan view, a light source spaced apart from the bottom portion in a direction in a plan view, and a display panel disposed below the window. The display panel may include a light sensing device, and may include a display region overlapping the transmission region in a plan view.

In an embodiment, the bottom portion may include a first bottom surface parallel to the top surface, and a second bottom surface which is connected to the first bottom surface and the side portion and is inclined with respect to the first bottom surface.

In an embodiment, an angle between the first and second bottom surfaces may be equal to or greater than about 165° and may be smaller than or equal to about 175°.

In an embodiment, the display device may further include an optical layer disposed between the bottom portion of the window and the light-blocking layer. The optical layer may overlap an entire region of the light-blocking and transmission regions in a plan view.

In an embodiment, a refractive index of the optical layer may be lower than a refractive index of the window.

In an embodiment, in case that the refractive index of the window is about 1.5, the refractive index of the optical layer may be equal to or greater than about 1.3 and may be equal to or smaller than about 1.4.

In an embodiment, the side portion may include a first side surface connected to the bottom portion, and a second side surface connected to the top surface and the first side surface and is inclined with respect to the first side surface. The light source may face the first side surface.

In an embodiment, the second side surface may overlap the light source in a plan view.

In an embodiment, an angle between the first side surface and the second side surface may be equal to or greater than about 165° and may be smaller than about 180°.

In an embodiment, the display device may further include an additional light-blocking layer disposed on the second side surface.

In an embodiment, the display device may further include a reflection facing the side portion of the window. The light source may be disposed between the reflection part and the side portion of the window.

In an embodiment, the display device may further include a first optical portion, which is attached to a portion of the bottom portion and has a first inclined surface inclined with respect to the bottom portion, and a second optical portion, which is attached to the side portion and has a second inclined surface inclined with respect to the side portion.

In an embodiment, the display device may further include an adhesive member attaching each of the first and second optical portions to the window.

In an embodiment, the display device may further include an additional light-blocking layer disposed on the second inclined surface.

In an embodiment, an angle between the first inclined surface and the bottom portion may be equal to or greater than about 165° and is equal to or smaller than about 175°, and an angle between the second inclined surface and the side portion may be equal to or greater than about 165° and is smaller than about 180°.

In an embodiment, the light-blocking layer may be disposed between the first optical portion and the window.

In an embodiment, the side portion may include a first side surface which is connected to the bottom portion and is extended toward the top surface, a second side surface which is extended from the first side surface in a direction parallel to the top surface, and a third side surface which is extended from the second side surface toward the top surface. The light source may be disposed to face the first side surface and the second side surface.

In an embodiment, the display device may further include an additional light-blocking layer disposed on the second side surface.

In an embodiment, the light-blocking layer may transmit infrared light and reflect visible light.

According to an embodiment of the disclosure, a display device may include a window including a top surface, a bottom portion facing the top surface, and a side portion connecting the top surface to the bottom portion and the window including a transmission region and a light-blocking region, a light-blocking layer disposed below the window and overlapping the light-blocking region in a plan view, a light source spaced apart from the bottom portion in a direction in a plan view, and a display panel disposed below the window. The display panel may include a light sensing device and may include a display region overlapping the transmission region in a plan view. The bottom portion may include a first bottom surface which is parallel to the top surface, and a second bottom surface which is connected to the first bottom surface and the side portion and is inclined with respect to the first bottom surface. An angle between the first and second bottom surfaces may be equal to or greater than about 165° and may be smaller than about 180°.

In an embodiment, the display device may further include an optical layer disposed between the bottom portion of the window and the light-blocking layer. The optical layer may overlap an entire region of the light-blocking and transmission regions in a plan view.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic perspective view illustrating a display device according to an embodiment of the disclosure.

FIG. 2 is a schematic exploded perspective view illustrating a display device according to an embodiment of the disclosure.

FIG. 3 is a schematic sectional view illustrating a portion of a display device according to an embodiment of the disclosure.

FIG. 4 is a schematic enlarged view illustrating a portion (e.g., AA′ of FIG. 3) of a display device.

FIGS. 5A and 5B are schematic diagrams illustrating optical paths of light reflected by the structure of FIG. 4.

FIG. 6A is a schematic diagram illustrating an optical path of light in a structure in which a light source according to a comparative example is disposed on a side surface of a window.

FIG. 6B is a schematic diagram illustrating an optical path of light in a structure in which a light source according to a comparative example is disposed below a window.

FIG. 7 is a graph showing irradiances in the structures of FIGS. 4, 6A, and 6B.

FIGS. 8 and 9 are schematic enlarged views illustrating a portion (e.g., AA′ of FIG. 3) of a display device.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF THE EMBODIMENTS

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, optical, and/or fluid connection, with or without intervening elements.

Additionally, if elements are described as being “connected,” the elements may be two separate elements connected to each other or may be integral with each other.

In the drawings, the thicknesses of layers and regions may be exaggerated for clarity. Like reference numerals in the drawings denote like elements, and thus their description will be omitted.

It will be understood that, although the terms “first”, “second”, and the like may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

The term “part” or “unit” used in the embodiment may be a software component or a hardware component, which is configured to execute a specific function. The hardware component may include a field programmable gate array (FPGA) or an application specific integrated circuit (ASIC). The software component may refer to data used by executable code and/or data, which are stored in an addressable storage medium and are used by the executable code. Thus, the software components may be, for example, object-oriented software components, class components, and work components and may include processes, functions, properties, procedures, subroutines, program code segments, drivers, firmwares, microcodes, circuits, data, database, data structures, tables, arrays, or variables.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by one of ordinary skill in the art to which example embodiments of the disclosure belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Example embodiments of the disclosure will now be described more fully with reference to the accompanying drawings, in which example embodiments are shown.

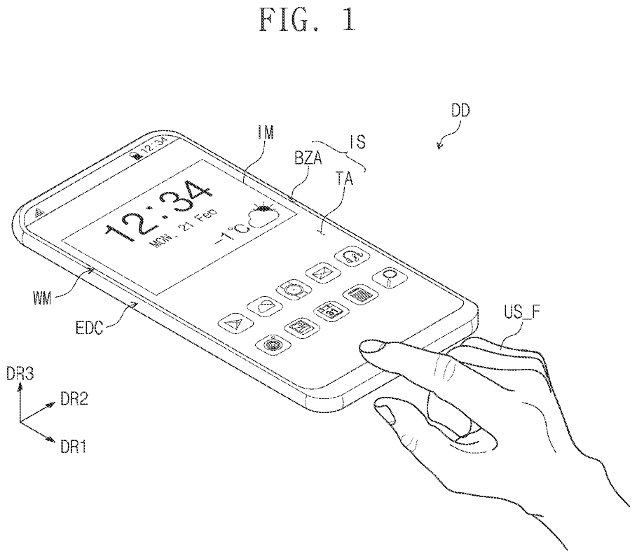

FIG. 1 is a schematic perspective view illustrating a display device DD according to an embodiment of the disclosure.

Referring to FIG. 1, the display device DD may be a device that is activated by an electrical signal applied thereto. For example, the display device DD may be a cellular phone, a tablet personal computer (PC), a car navigation system, a gaming machine, or a wearable device but is not limited to these examples. FIG. 1 illustrates an example, in which the display device DD is a cellular phone.

A top surface of the display device DD may be defined as a display surface IS and may have a flat surface or plane defined by a first direction DR1 and a second direction DR2. Images IM, which are produced by the display device DD, may be provided to a user through the display surface IS. Hereinafter, a direction, which is perpendicular or normal to the plane defined by both of the first and second directions DR1 and DR2, will be referred to as a third direction DR3. Furthermore, in the specification, the expression “when viewed in a plan view” or “in a plan view” may mean that a relevant structure is seen in the third direction DR3. In other words, the plan view may be parallel to the plane defined by the first direction DR1 and the second direction DR2.

The display surface IS may include a transmission region TA and a bezel region BZA. In the embodiment, the transmission region TA is illustrated to have a rectangular shape with rounded corners. However, the disclosure is not limited to this example, and in an embodiment, the shape of the transmission region TA may be variously changed.

The bezel region BZA may be adjacent to the transmission region TA. In the embodiment, the bezel region BZA may be referred to as a light-blocking region BZA. The bezel region BZA may have a color (e.g., a predetermined or selectable color). The bezel region BZA may be provided to enclose the transmission region TA. Thus, the shape of the transmission region TA may be substantially defined by the bezel region BZA. However, the disclosure is not limited to this example, and in an embodiment, the bezel region BZA may be provided near at least one of sides of the transmission region TA or may be omitted.

The display device DD may sense an external input provided from the outside. The external input may include various types of input signals, which are provided from the outside of the display device DD. For example, the external input may include a touching-type external input, such as a user's hand US_F, and a non-touching-type external input, such as reduction of a distance to the display device DD or a hovering event near the display device DD. The external input may be provided in various forms, such as force, pressure, temperature, and light. The external input may be provided by an additional device (e.g., an active pen or a digitizer pen).

The display device DD may sense a user's biometric data, which is provided from the outside. A biometric information sensing region, which can sense the user's biometric data, may be provided on the display surface IS of the display device DD. The biometric information sensing region may be provided throughout the transmission region TA or may be provided in a portion of the transmission region TA. FIG. 1 illustrates an example in which the entirety of the transmission region TA is used as the biometric information sensing region, but the disclosure is not limited to this example. For example, the biometric information sensing region may be provided in a portion of the transmission region TA.

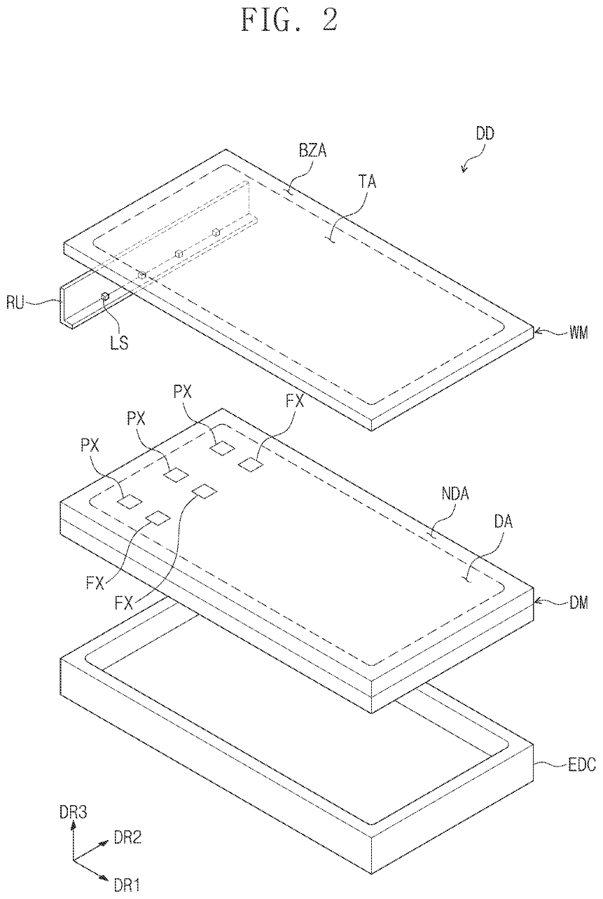

FIG. 2 is a schematic exploded perspective view illustrating the display device DD according to an embodiment of the disclosure.

Referring to FIG. 2, the display device DD may include a window WM, a display module DM, a light source LS, a reflection part RU, and a housing EDC. The window WM and the housing EDC may be combined to define an outer appearance (or exterior) of the display device DD and to have an internal space, which is used to contain parts (e.g., the display module DM) of the display device DD.

The window WM may be disposed on the display module DM. The window WM may protect the display module DM from an external impact. A front surface of the window WM may correspond to the display surface IS of the display device DD described with reference to FIG. 1. The front surface of the window WM may include the transmission region TA and the bezel region BZA.

The window WM may be formed of or include an optically transparent insulating material. For example, the window WM may be formed of or include at least one of glass, sapphire, or plastic materials. The window WM may have a single- or multi-layered structure. The window WM may further include a functional layer (e.g., an anti-fingerprint layer, a phase control layer, or a hard coating layer) which is disposed on an optically transparent substrate.

The transmission region TA of the window WM may be an optically transparent region. The transmission region TA of the window WM may be configured to transmit an image, which is produced by the display module DM, and the image may be recognized by a user.

The bezel region BZA may be a region of the window WM, which is formed by depositing, coating, or printing a material of a specific color on a transparent substrate. The bezel region BZA of the window WM may prevent a part of the display module DM, which is disposed to be overlapped with (or to overlap) the bezel region BZA, from being recognized by a user.

The reflection part RU may be disposed on a section or an end of the window WM. However, the position of the reflection part RU is not limited thereto. For example, the reflection part RU may be disposed on a long side of the window WM or may be disposed on short and long sides of the window WM.

The light source LS may be disposed on the reflection part RU. The light source LS may have a chip-on-board (COB) structure. The light source LS may be a chip-shaped element disposed on a substrate. FIG. 2 illustrates an example in which four light sources LS are disposed on the short side of the window WM, but the number and disposition of the light source LS are not limited thereto. For example, the number of the light source LS may be smaller than or equal to 3 or may be greater than or equal to 5. The light source LS may be disposed on the long side of the window WM or may be formed on the short and long sides of the window WM.

The display module DM may be disposed between the window WM and the housing EDC. The display module DM may be configured to display an image in response to an electrical signal applied thereto. The display module DM may include a display region DA and a non-display region NDA adjacent to the display region DA.

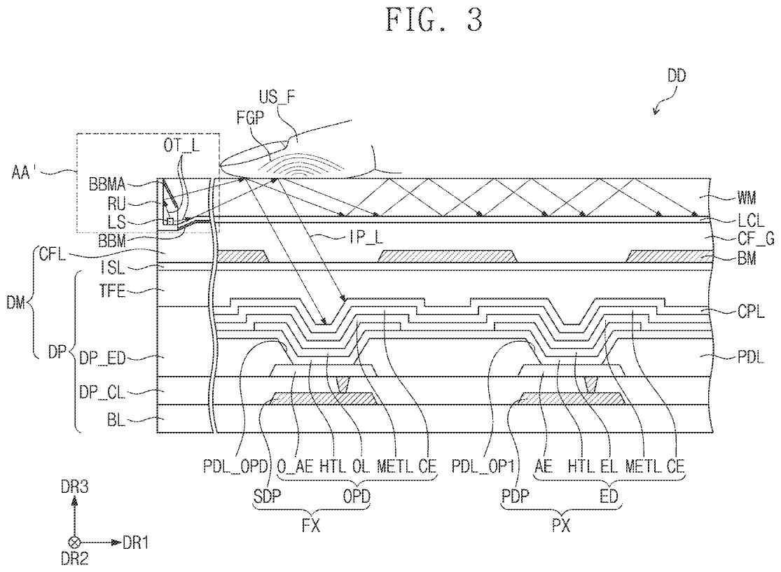

The display region DA may be a region that is activated by electrical signals applied thereto. An image, which is provided from a display panel DP (e.g., see FIG. 3), may be emitted to the outside through the display region DA. The display region DA of the display module DM may be overlapped with at least a portion of the transmission region TA. An image, which is output through the display region DA, may be recognized by a user through the transmission region TA.

The non-display region NDA may be adjacent to the display region DA. For example, the non-display region NDA may be provided to enclose the display region DA. However, the disclosure is not limited to this example, and in an embodiment, the shape of the non-display region NDA may be variously changed. Driving circuits or driving lines, which are used to drive devices disposed in the display region DA, and various signal lines and pads, which are used to deliver electrical signals to the devices, may be disposed in the non-display region NDA. The non-display region NDA may be overlapped with at least a portion of the bezel region BZA, and the bezel region BZA may prevent parts of the display module DM, disposed in the non-display region NDA, from being recognized by a user.

The display module DM may include pixels PX, which are disposed in the display region DA, and sensors FX, which are disposed in the display region DA. FIG. 2 illustrates an example in which the pixels PX and the sensors FX are arranged with a constant distance or at intervals in the second direction DR2, but the arrangement of the pixels PX and the sensors FX is not limited to this example. For example, each of the sensors FX may be disposed between two adjacent pixels PX, and the pixels PX and the sensors FX may be alternately disposed in the first direction DR1 and the second direction DR2. The sensors FX may be configured to reflection light IP-L that is a fraction of infrared light OT-L (e.g., see FIG. 3), which is emitted from the light source LS and is reflected by a fingerprint US_F (e.g., see FIG. 3).

The housing EDC may be disposed below the display module DM to contain the display module DM. The housing EDC may be formed of or include a material having a relatively high stiffness or strength. For example, the housing EDC may include at least one of glass, plastic, or metallic materials or may include frames and/or plates that are made of the glass, plastic, or metallic materials. The housing EDC may stably protect elements of the display device DD, which are disposed in the internal space, from an external impact. Although not shown, a battery module, which supplies electric power for operations of the display device DD, may be disposed between the display module DM and the housing EDC.

FIG. 3 is a schematic sectional view illustrating a portion of the display device DD according to an embodiment of the disclosure. FIG. 3 illustrates a process of sensing a fingerprint FGP, which is at least one of biometric data input through the hand US_F of the user, using the sensor FX.

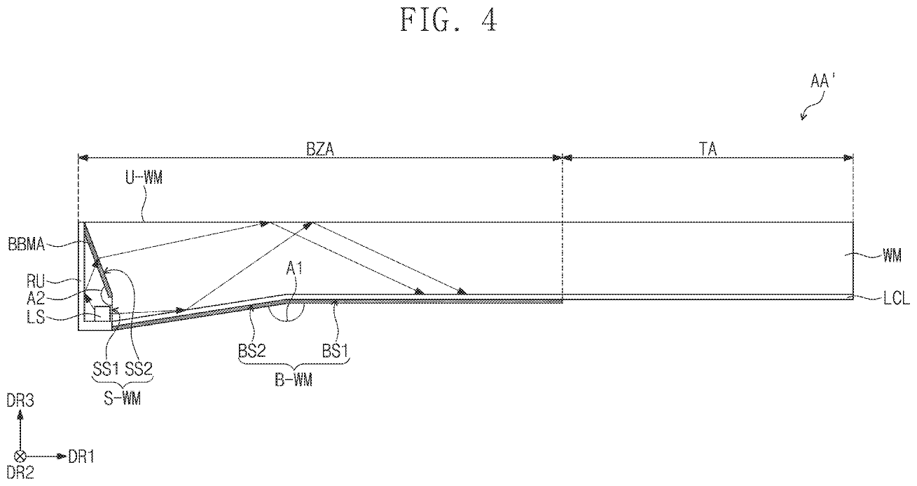

Referring to FIG. 3, the display device DD may include the display module DM, an optical layer LCL, a light-blocking layer BBM, an additional light-blocking layer BBMA, the light source LS, the reflection part RU, and the window WM. The optical layer LCL, the light-blocking layer BBM, the additional light-blocking layer BBMA, the light source LS, the reflection part RU, and the window WM will be described in more detail with reference to FIG. 4.

The display module DM may include a display panel DP, an input-sensing layer ISL, and an anti-reflection layer CFL. The display panel DP may include a base layer BL, a circuit layer DP_CL, a device layer DP_ED, and an encapsulation layer TFE.

The display panel DP may be an element, which is used to substantially produce an image. The display panel DP may be a light-emitting type display panel (e.g., an organic light-emitting display panel, an inorganic light-emitting display panel, an organic-inorganic light-emitting display panel, a quantum dot display panel, a micro-light-emitting diode (LED) display panel, or a nano-LED display panel). For the sake of simplicity, the description that follows will refer to an example in which the display panel DP is the organic light-emitting display panel.

In an embodiment, the display panel DP may be a flexible display panel. However, the disclosure is not limited to this example. For example, the display panel DP may be a foldable display panel, which can be folded along a folding axis, or a rigid display panel.

The base layer BL may include a synthetic resin layer. The synthetic resin layer may be a polyimide-based resin layer, and the material of the base layer BL is not limited to a specific material. The base layer BL may include a glass substrate, a metal substrate, or an organic/inorganic composite substrate.

The circuit layer DP_CL may be disposed on the base layer BL. The circuit layer DP_CL may include at least one insulating layer and a circuit device. Hereinafter, the insulating layer in the circuit layer DP_CL will be referred to as an intermediate insulating layer. The intermediate insulating layer may include at least one intermediate inorganic layer and at least one intermediate organic layer. The circuit device DP_CL may include a pixel driving circuit (not shown), which is disposed in each of the pixels PX to display an image, and a sensor driving circuit (not shown), which is disposed in each of the sensors FX to sense external information. The external information may be biometric information of a user. In an embodiment, the sensor FX may be a fingerprint recognition sensor, a proximity sensor, an iris recognition sensor, or the like. The sensor FX may be an optical sensor, which is configured to recognize the biometric data in an optical manner. The circuit layer DP_CL may further include signal lines, which are connected to the pixel driving circuit (not shown) and/or the sensor driving circuit (not shown).

The device layer DP_ED may be disposed on the circuit layer DP_CL. The device layer DP_ED may include a light-emitting device ED, which are included in each of the pixels PX, and a light sensing device OPD, which is included in each of the sensors FX. In an embodiment, the light sensing device OPD may be a photodiode. The light sensing device OPD may be a sensor, which is configured to sense or response to light reflected by the fingerprint FGP. The device layer DP_ED may include the light sensing device OPD of the sensor FX, the light-emitting device ED of the pixel PX, a pixel definition layer PDL, and a capping layer CPL.

The pixel PX may include the light-emitting device ED and a pixel driving part PDP. The light-emitting device ED may include an organic light-emitting device or a quantum dot light-emitting device. However, the disclosure is not limited to this example, and various devices can be used as the light-emitting device ED, as long as they can emit light in case that an electrical signal is applied thereto or an amount of the light can be controlled by the electrical signal.

The sensor FX may include the light sensing device OPD and a sensor driving part SDP. The light sensing device OPD may be an optical sensor that is configured to sense infrared light reflected by an external object. In an embodiment, the light sensing device OPD may be a biometric sensing device, which is configured to sense light reflected by a portion (e.g., a fingerprint or a vein) of a human body and to convert the light to an electrical signal.

The infrared light OT-L, which is emitted from the light source LS, may be reflected by an external object US_F (e.g., a fingerprint) to produce the reflection light IP-L that is incident into the light sensing device OPD. The reflection light IP-L, which is incident into the light sensing device OPD, may be light of an infrared wavelength. The light sensing device OPD may convert the incident reflection light IP-L to an electrical signal.

The light sensing device OPD may include an anode O_AE, a hole control layer HTL, a photoelectric conversion layer OL, an electron control layer METL, and a cathode CE.

The anode O_AE may be disposed on the circuit layer DP_CL. The anode O_AE may be exposed through a light sensing opening PDL_OPD of the pixel definition layer PDL. The anode O_AE may be formed of or include at least one of metallic materials, metal alloys, or conductive compounds.

However, the materials and properties of the anode O_AE are not limited thereto. For example, the anode O_AE may be a pixel electrode or a sensing electrode. The anode O_AE may be a transmissive electrode, a transflective electrode, or a reflective electrode. In case that the anode O_AE is the transmissive electrode, the anode O_AE may be formed of or include at least one of transparent metal oxide materials (e.g., indium tin oxide (ITO), indium zinc oxide (IZO), zinc oxide (ZnO), and indium tin zinc oxide (ITZO)). In case that the anode O_AE is the transflective electrode or the reflective electrode, the anode O_AE may be formed of or include at least one of Ag, Mg, Cu, Al, Pt, Pd, Au, Ni, Nd, Ir, Cr, Li, Ca, LiF/Ca, LiF/Al, Mo, Ti, W, compounds thereof, or mixtures thereof (e.g., a mixture of Ag and Mg).

The hole control layer HTL may be disposed on the anode O_AE and the pixel definition layer PDL. The hole control layer HTL may be a single-layered structure, which is formed of a single material or of different materials, or a multi-layered structure including layers, which are formed of different materials. For example, the hole control layer HTL may have a single-layered structure, which has at least one of a hole injection layer or a hole transport layer or contains both of a hole injection material and a hole transport material. In an embodiment, the hole control layer HTL may include a hole transport layer and may further include a hole injection layer.

The photoelectric conversion layer OL may be disposed on the hole control layer HTL. The photoelectric conversion layer OL may include a light-receiving material capable of converting incident light to an electrical signal. In an embodiment, the photoelectric conversion layer OL may be formed of or include an organic light-receiving material. However, the material of the photoelectric conversion layer OL is not limited thereto. For example, an organic polymer material may be used as the light-receiving material of the photoelectric conversion layer OL, and in an embodiment, the photoelectric conversion layer OL may include at least one of conjugated polymers. The photoelectric conversion layer OL may include thiophene-based conjugated polymer, benzodithiophene-based conjugated polymer, thieno [3,4-c]pyrrole-4,6-dione (TPD)-based conjugated polymer, diketo-pyrrolo-pyrrole (DPP)-based conjugated polymer, benzothiadiazole (BT)-based conjugated polymer, and so forth.

The electron control layer METL may be disposed on the photoelectric conversion layer OL, a light-emitting layer EL, and the hole control layer HTL. In other words, the electron control layer METL may be provided in the form of a single body. The electron control layer METL may be a single-layered structure, which is formed of a single material or of different materials, or a multi-layered structure including layers, which are formed of different materials. For example, the electron control layer METL may have a single-layered structure, which has one of an electron injection layer and an electron transport layer or contains both of an electron injection material and an electron transport material. In an embodiment, the electron control layer METL may have a single-layered structure, which is formed of different materials, or may further include layers, which are sequentially stacked each other on the light-emitting layer EL. In an embodiment, the electron control layer METL may include an electron transport layer and may further include an electron injection layer.

The cathode CE may be disposed on the electron control layer METL and may be formed simultaneously by a same process. In other words, the cathode CE may be provided in the form of a single body. The cathode CE may be a common electrode. However, the disclosure is not limited to this example. For example, the cathode CE may be a transmissive electrode, a transflective electrode, or a reflective electrode. In case that the cathode CE is the transmissive electrode, the cathode CE may be formed of or include at least one of transparent metal oxide materials (e.g., indium tin oxide (ITO), indium zinc oxide (IZO), zinc oxide (ZnO), and indium tin zinc oxide (ITZO)). In case that the cathode CE is the transflective electrode or the reflective electrode, the cathode CE may be formed of or include at least one of Ag, Mg, Cu, Al, Pt, Pd, Au, Ni, Nd, Ir, Cr, Li, Ca, LiF/Ca, LiF/Al, Mo, Ti, W, compounds thereof, or mixtures thereof (e.g., a mixture of Ag and Mg).

The sensor driving part SDP may be disposed in the circuit layer DP_CL. The sensor driving part SDP may include a sensor driving circuit (not shown), which is connected to the light sensing device OPD to drive the light sensing device OPD.

The light-emitting device ED may include an anode AE, the hole control layer HTL, the light-emitting layer EL, the electron control layer METL, and the cathode CE. The anode AE, the hole control layer HTL, the electron control layer METL, and the cathode CE of the light-emitting device ED may be configured to have substantially the same features as the anode O_AE, the hole control layer HTL, the electron control layer METL, and the cathode CE of the light sensing device OPD described above.

The light-emitting layer EL may be disposed on the hole control layer HTL. The light-emitting layer EL may be a green light-emitting layer, but the disclosure is not limited to this example. The light-emitting layer EL may be formed of or include at least one of organic and/or inorganic materials. The light-emitting layer EL may be configured to generate color light. The light-emitting layer EL may include an organic light-emitting material or may include a quantum dot material.

The pixel driving part PDP may be disposed in the circuit layer DP_CL. The pixel driving part PDP may include a pixel driving circuit (not shown), which is connected to the light-emitting device ED and is used to drive the light-emitting device ED.

The pixel definition layer PDL may be disposed on the circuit layer DP_CL. A first opening PDL_OP1 and the light sensing opening PDL_OPD may be defined in the pixel definition layer PDL. The light-emitting layer EL may be disposed in the first opening PDL_OP1, and the photoelectric conversion layer OL may be disposed in the light sensing opening PDL_OPD. To avoid complexity in the drawings, FIG. 3 illustrates only the first opening PDL_OP1 and the light sensing opening PDL_OPD.

In an embodiment, the pixel definition layer PDL may further include a black material. For example, the pixel definition layer PDL may further include a black organic dye/pigment, such as carbon black or aniline black. The pixel definition layer PDL may be a layer that is formed by mixing blue and black organic materials with each other. The pixel definition layer PDL may further include an organic material having a liquid-repellent property.

The capping layer CPL may be disposed on the cathode CE to cover the cathode CE.

The encapsulation layer TFE may be provided to hermetically seal or encapsulate the device layer DP_ED. The encapsulation layer TFE may include at least one organic layer and at least one inorganic layer. The inorganic layer may be formed of or include an inorganic material and may protect the device layer DP_ED from moisture or oxygen. The inorganic layer may include a silicon nitride layer, a silicon oxynitride layer, a silicon oxide layer, a titanium oxide layer, an aluminum oxide layer, or the like but the disclosure is not limited to these examples. The organic layer may be formed of or include an organic material and may protect the device layer DP_ED from a contamination material such as dust particles.

The input-sensing layer ISL may be formed on the display panel DP. The input-sensing layer ISL may be directly disposed on the encapsulation layer TFE. In an embodiment, the input-sensing layer ISL may be formed on the display panel DP through successive processes. For example, in case that the input-sensing layer ISL is directly disposed on the display panel DP, an adhesive film may not be disposed between the input-sensing layer ISL and the encapsulation layer TFE. As another example, an adhesive film may be disposed between the input-sensing layer ISL and the display panel DP. In this case, the input-sensing layer ISL and the display panel DP may not be fabricated in a successive manner; for example, the input-sensing layer ISL may be fabricated by a process, which is different from a process for the display panel DP, and may be attached to a top surface of the display panel DP by an adhesive film.

The input-sensing layer ISL may sense an external input (e.g., a touch event from a user), may convert the sensed external input to an input signal, and may provide the input signal to the display panel DP. The input-sensing layer ISL may include sensing electrodes, which are used to sense the external input. The sensing electrodes may sense the external input in a capacitive manner. The display panel DP may receive an input signal from the input-sensing layer ISL and may generate an image corresponding to the input signal.

The anti-reflection layer CFL may be disposed on the input-sensing layer ISL. The anti-reflection layer CFL may be configured to reduce reflectance of external light incident from the outside of the display device DD. The anti-reflection layer CFL may be formed on the input-sensing layer ISL through a successive process, but the disclosure is not limited to this example. For example, the anti-reflection layer CFL may be disposed between the display panel DP and the input-sensing layer ISL.

The anti-reflection layer CFL may include a light-blocking pattern BM and color filters. The color filters may include a red color filter, a green color filter CF_G, and a blue color filter, and here, the green color filter CF_G is illustrated in FIG. 3. The light-blocking pattern BM may be disposed on the input-sensing layer ISL. The green color filter CF_G may be disposed on the light-blocking pattern BM and the input-sensing layer ISL to cover the light-blocking pattern BM. The light-blocking pattern BM may prevent a light leakage phenomenon and may delimit a boundary between adjacent ones of color filters having different colors from each other.

FIG. 3 illustrates an example in which the anti-reflection layer CFL includes the light-blocking pattern BM and the color filter CF_G, but the disclosure is not limited to this example. In an embodiment, the anti-reflection layer CFL may include a reflection adjustment layer (not shown), which is disposed on the light-blocking pattern BM, instead of the color filter CF_G. The reflection adjustment layer may be configured to selectively absorb light, which is reflected by the display panel DP and/or an internal element of the electronic device or to selectively absorb light, which is incident from the outside of the display panel DP and/or the electronic device and has a specific wavelength.

The light-blocking pattern BM may be a black matrix. The light-blocking pattern BM may include organic pigment or dye. The light-blocking pattern BM may be formed of or include at least one of organic or inorganic light-blocking materials containing black pigment or black dye. The light-blocking pattern BM may be formed of or include a light-blocking compound containing at least one of propylene glycol monomethyl ether acetate, 3-methoxybutyl acetate, or organic black pigment. The light-blocking pattern BM may be overlapped with the pixel definition layer PDL.

In an embodiment, the display device DD may further include an adhesive layer (not shown). The window WM may be attached to the anti-reflection layer CFL by an adhesive layer (not shown). The adhesive layer (not shown) may be formed of or include at least one of optical clear adhesive, optically clear adhesive resin, or pressure sensitive adhesive (PSA).

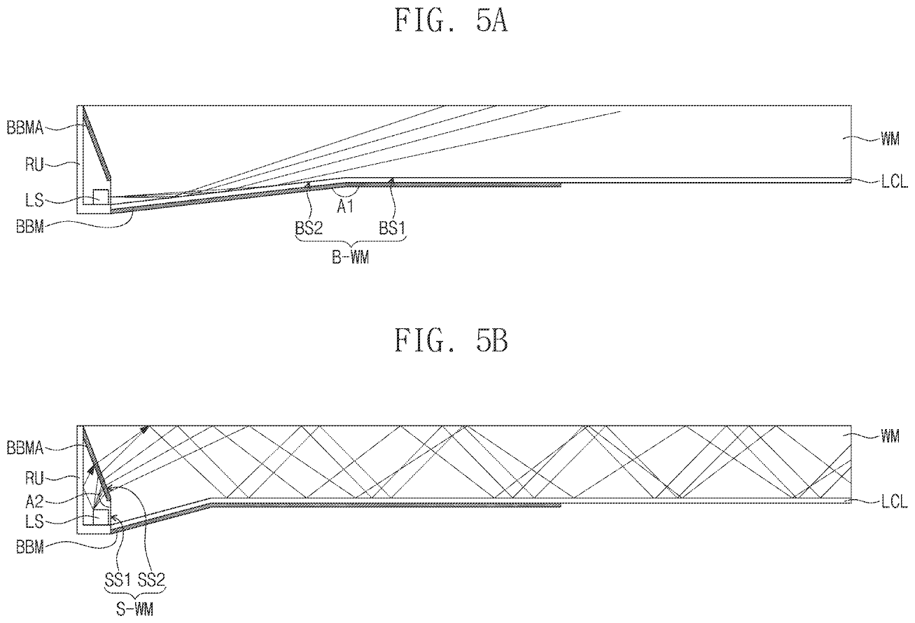

FIG. 4 is a schematic enlarged view illustrating a portion (e.g., AA′ of FIG. 3) of the display device DD. FIGS. 5A and 5B are schematic diagrams illustrating optical paths of light reflected by the structure of FIG. 4.

Referring to FIGS. 3 and 4, the window WM may be provided as the topmost element of the display device DD. The window WM may include a top surface U-WM, a bottom portion B-WM, and a side portion S-WM. In the embodiment, the window WM may be used as a light guide plate. In other words, the window WM may be configured to uniformly provide light, which is emitted from the light source LS, to the entire region of the display surface IS (e.g., see FIG. 1).

The bottom portion B-WM may be provided to be opposite to the top surface U-WM. The bottom portion B-WM may include a first bottom surface BS1 and a second bottom surface BS2. The first bottom surface BS1 may be parallel to the top surface U-WM. The second bottom surface BS2 may be connected to (or extend from/to) the first bottom surface BS1 and the side portion S-WM and may be inclined at a first angle A1 with respect to the first bottom surface BS1. The first angle A1 between the first and second bottom surfaces BS1 and BS2 may be greater than or equal to about 165° and may be smaller than or equal to about 175°.

The side portion S-WM may connect the top surface U-WM to the bottom portion B-WM. The side portion S-WM may include a first side surface SS1 and a second side surface SS2. The first side surface SS1 may be connected to the bottom portion B-WM. The second side surface SS2 may be connected to the top surface U-WM and the second side surface SS2 and may be inclined at a second angle A2 with respect to the first side surface SS1. The second angle A2 between the first and second side surfaces SS1 and SS2 may be greater than or equal to about 165° and may be smaller than about 180°. For example, the second angle A2 may be greater than or equal to about 173.6°.

The optical layer LCL may be disposed on the anti-reflection layer CFL. For example, the optical layer LCL may be disposed between the bottom portion B-WM of the window WM and the light-blocking layer BBM and between the bottom portion B-WM and the anti-reflection layer CFL. The optical layer LCL may be fully overlapped with both of the light-blocking region BZA and the transmission region TA. A refractive index of the optical layer LCL may be lower than a refractive index of the window WM. For example, in case that the refractive index of the window WM is about 1.5, the refractive index of the optical layer LCL may be higher than or equal to about 1.3 and may be lower than or equal to about 1.4. However, the refractive index of the optical layer LCL is not limited to this value.

The optical layer LCL may further include hollow particles and/or voids, which are dispersed in an organic layer, and the refractive index of the optical layer LCL may be adjusted by a ratio of the hollow particles and/or the voids. By totally reflecting light, which is emitted from the light source LS, using the refractive index of the optical layer LCL, the reflected light may be re-incident into the window WM. In other words, light emitted from the light source LS may propagate in the window WM through the total reflection, and thus, it may be possible to increase a light amount throughout the window WM and to improve optical efficiency of the window WM.

The light-blocking layer BBM may be disposed below the window WM, and the additional light-blocking layer BBMA may be disposed on the second side surface SS2. The additional light-blocking layer BBMA and the light-blocking layer BBM may have a same material and function. The light-blocking layer BBM and the additional light-blocking layer BBMA may be formed of or include a material that transmits infrared light and reflects visible light. Each of the light-blocking layer BBM and the additional light-blocking layer BBMA may be a print layer, which is printed on the window WM, or a film, which is attached to the window WM.

The light-blocking layer BBM may be disposed on a portion of a bottom surface of the optical layer LCL. The light-blocking layer BBM may define the transmission region TA and the light-blocking region BZA. For example, a region, which is overlapped with the light-blocking layer BBM, may be defined as the light-blocking region BZA, and a region, which is not overlapped with the light-blocking layer BBM, may be defined as the transmission region TA.

The light-blocking layer BBM may be configured to transmit the infrared light and to reflect or absorb the visible light. For example, the light-blocking layer BBM may block the visible light and may totally reflect only the infrared light incident into the window WM.

In a plan view, the light source LS may be spaced apart from the bottom portion B-WM in the first direction DR1. For example, the light source LS may be disposed to face the first side surface SS1 and to be overlapped with the second side surface SS2. The light source LS may be configured to emit infrared light. For example, the light source LS may emit light whose wavelength ranges from about 700 nm to about 1000 nm.

The reflection part RU may be disposed to face the side portion S-WM of the window WM, with the light source LS interposed therebetween. The reflection part RU may be configured to cause a specular reflection. For example, the light may be incident on the reflective part RU, which is a flat mirror, and a reflection may occur with the plane of the reflective part RU as a boundary. The infrared light, which is emitted from the light source LS, may be reflected by the reflection part RU and may be incident into the window WM through the additional light-blocking layer BBMA. Since the light emitted from the light source LS is directly or indirectly incident into the window WM and propagates in the window WM through the total reflection, and thus, it may be possible to increase a light amount throughout the window WM and to improve optical efficiency of the window WM.

Referring to FIGS. 4 and 5A, due to the first angle A1 between the first and second bottom surfaces BS1 and BS2, light, which is incident through the second bottom surface BS2, may be totally reflected into the window WM. Thus, infrared light which is used to sense the fingerprint FGP may be incident into the window WM, and visible light may be prevented from being emitted to the outside of the window WM. The window WM may be more effectively used as the light guide plate.

Referring to FIGS. 4 and 5B, due to the second angle A2 between the first and second side surfaces SS1 and SS2, light, which is incident through the second side surface SS2, may be totally reflected in the window WM. Thus, infrared light which is used to sense the fingerprint FGP may be incident into the window WM, and visible light may be prevented from being emitted to the outside of the window WM. The window WM may be more effectively used as the light guide plate.

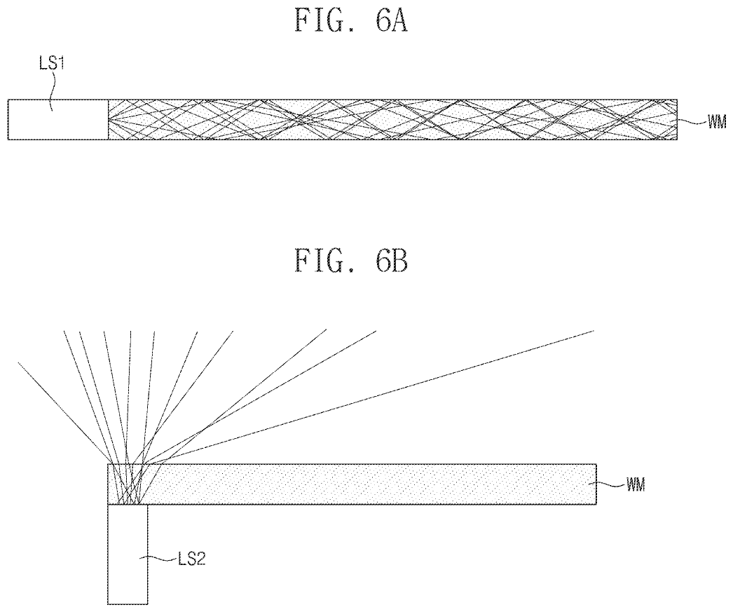

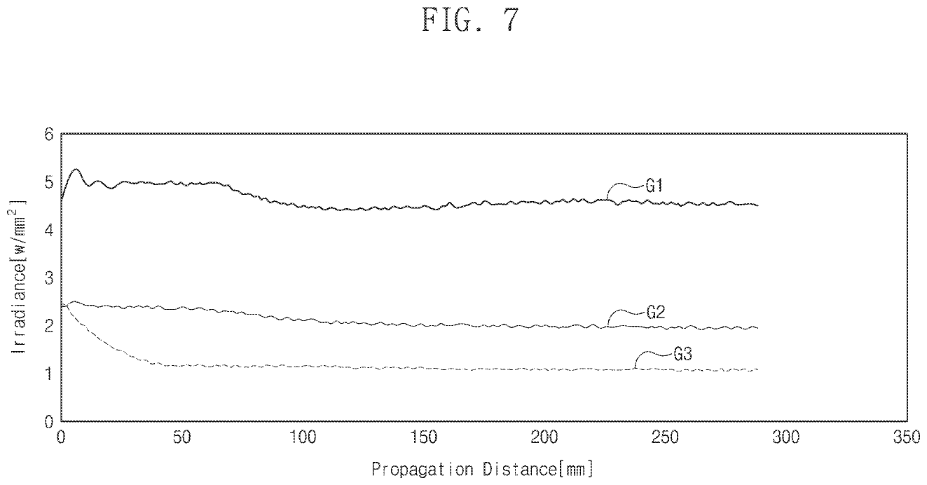

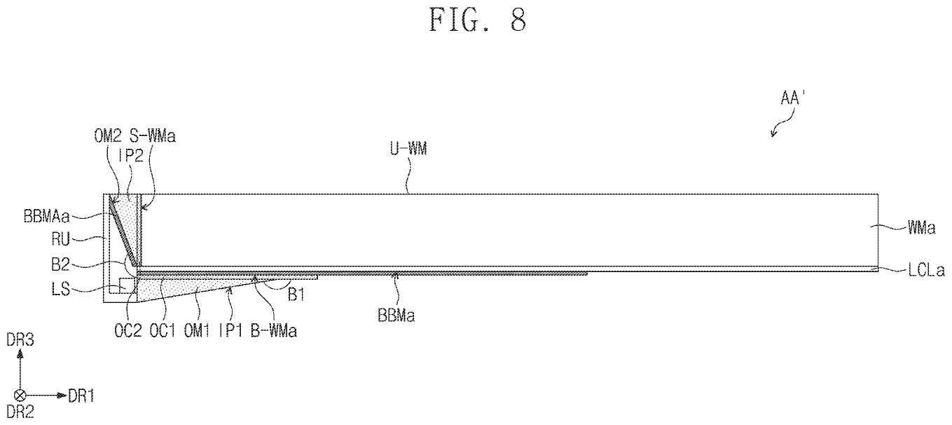

FIG. 6A is a schematic diagram illustrating an optical path of light in a structure in which a light source LS1 (hereinafter, a first external light source) according to a comparative example is disposed on a side surface of the window WM, and FIG. 6B is a schematic diagram illustrating an optical path of light in a structure in which a light source LS2 (hereinafter a second external light source) according to a comparative example is disposed below the window WM. FIG. 7 is a schematic graph illustrating irradiances in the structures of FIGS. 4, 6A, and 6B.

Referring to FIG. 6A, the first external light source LS1 may be disposed on a side surface of the window WM. Light emitted from the first external light source LS1 may be incident into the window WM, and the window WM may be used as a light guide plate. However, since the first external light source LS1 is disposed on the side surface of the window WM, a width of the light-blocking region BZA (e.g., see FIG. 1) may be increased, and an additional structure may be needed to shield the first external light source LS1.

Referring to FIG. 6B, the second external light source LS2 may be disposed below the window WM. For example, the second external light source LS2 may be in optical contact with a bottom surface of the window WM. For example, the second external light source LS2 and the window WM may be combined to each other via a medium layer, and in an embodiment, the medium layer may be silicon oxide, but the disclosure is not limited to this example. Light emitted from the second external light source LS2 may be incident into the window WM, but in this case, the window WM may not be used as the light guide plate. In other words, the incident light may not be provided to the entire region of the window WM and may be emitted toward the outside through a specific region of the window WM. Thus, an additional light guide plate may be needed to provide the light, which is provided from the second external light source LS2, to the entire region of the window WM.

Referring to FIGS. 4, 6A, 6B, and 7, in the graph of FIG. 7, the x- and y-axes represent a propagation distance and an irradiance. First, second, and third graphs G1, G2, and G3 in FIG. 7 show the irradiances with respect to propagation distances in the structures of FIGS. 4, 6A, and 6B. The irradiance in the first graph G1 was higher than those in the second and third graphs G2 and G3, and this means that the structure of FIG. 4 has an increased irradiance. Thus, according to an embodiment of the disclosure, it may be possible to reduce a width of the light-blocking region BZA and improve an irradiance property, without an additional structure for shielding the light source LS.

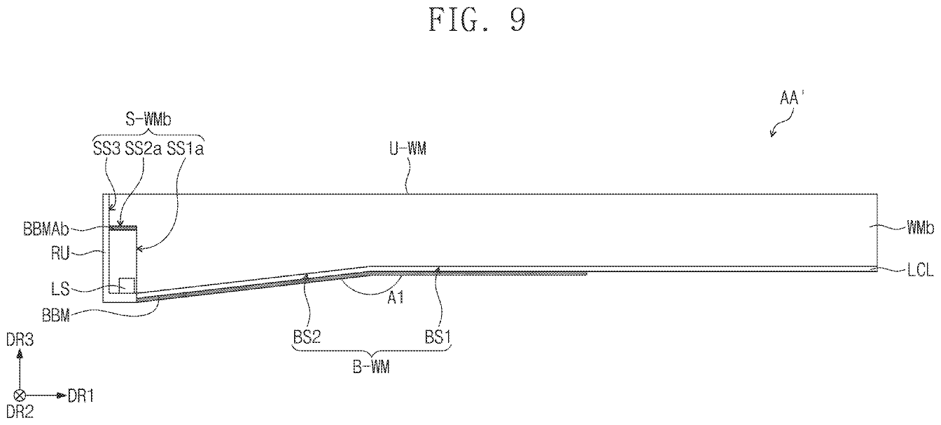

FIGS. 8 and 9 are schematic enlarged views illustrating a portion (e.g., AA′ of FIG. 3) of the display device DD. In the following description of FIGS. 8 and 9, an element previously described with reference to FIGS. 3 and 4 may be identified by the same reference number without repeating an overlapping description thereof, for the sake of brevity.

Referring to FIG. 8, the display device DD (e.g., see FIG. 3) may include the display module DM (e.g., see FIG. 3), an optical layer LCLa, a light-blocking layer BBMa, an additional light-blocking layer BBMAa, the light source LS, the reflection part RU, a first adhesive member OC1, a second adhesive member OC2, and a window WMa. FIG. 8 illustrates an example in which a window WMa has a rectangular shape, but the disclosure is not limited to this example.

The window WMa may include the top surface U-WM, a bottom portion B-WMa, and a side portion S-WMa connecting the top surface U-WM to the bottom portion B-WMa. In the embodiment, the window WMa may be used as a light guide plate. In other words, the window WMa may be used to uniformly provide light, which is emitted from the light source LS, to the display surface IS (e.g., see FIG. 1).

A first optical portion OM1 may be attached to a portion of the bottom portion B-WMa. For example, the first adhesive member OC1 may attach the first optical portion OM1 to the bottom portion B-WMa of the window WMa. However, the disclosure is not limited to this example, and in an embodiment, the first adhesive member OC1 may be omitted. The first optical portion OM1 may have a first inclined surface IP1. The first inclined surface IP1 may be inclined at a first angle B1 with respect to the bottom portion B-WMa of the window WMa. The first angle B1 may be greater than or equal to about 165° and may be smaller than or equal to about 175°.

A second optical portion OM2 may be attached to a side portion S-BMa. For example, the second adhesive member OC2 may attach the second optical portion OM2 to the side portion S-WMa of the window WMa. However, the disclosure is not limited to this example, and in an embodiment, the second adhesive member OC2 may be omitted. The second optical portion OM2 may have a second inclined surface IP2. The second inclined surface IP2 may be inclined at a second angle B2 with respect to the side portion S-BMa of the window WMa. The second angle B2 may be greater than or equal to about 165° and may be smaller than about 180°.

The first optical portion OM1 and the second optical portion OM2 may be formed of or include a material which has high transmittance and improved processability. According to the above structure, since the first and second optical portions OM1 and OM2 are attached to each other without an additional processing step on the window WMa, it may be possible to reduce a difficulty in a process of fabricating the display device DD and to improve light receiving efficiency of the display device DD.

The optical layer LCLa may be disposed on the anti-reflection layer CFL (e.g., see FIG. 3). For example, the optical layer LCLa may be disposed between the bottom portion B-WMa of the window WMa and the light-blocking layer BBMa and between the bottom portion B-WMa and the anti-reflection layer CFL. The optical layer LCL may be overlapped with the entire area of the light-blocking region BZA and the transmission region TA (e.g., see FIG. 4). A refractive index of the optical layer LCLa may be lower than a refractive index of the window WMa. For example, in case that the refractive index of the window WMa is about 1.5, the refractive index of the optical layer LCLa may be greater than or equal to about 1.3 and may be smaller than or equal to about 1.4. However, this is illustrative, and the refractive index of the optical layer LCLa is not limited to these values.

The light-blocking layer BBMa may be disposed between the window WMa and the first optical portion OM1 and between the window WMa and the anti-reflection layer CFL. The additional light-blocking layer BBMAa may be disposed on the second inclined surface IP2 of the second optical portion OM2. The additional light-blocking layer BBMAa and the light-blocking layer BBMa may have a same material and function.

Referring to FIG. 9, the display device DD (e.g., see FIG. 3) may include the display module DM (e.g., see FIG. 3), the optical layer LCL, the light-blocking layer BBM, an additional light-blocking layer BBMAb, the light source LS, the reflection part RU, and a window WMb.

The window WMb may include the top surface U-WM, the bottom portion B-WM, and a side portion S-WMb connecting the top surface U-WM to the bottom portion B-WM. In the embodiment, the window WMb may be used as a light guide plate. In other words, the window WMb may be used to uniformly provide light, which is emitted from the light source LS, to the display surface IS (e.g., see FIG. 1).

The side portion S-WMb of the window WMb may include a first side surface SS1a, a second side surface SS2a, and a third side surface SS3. The first side surface SS1a may be connected to the bottom portion B-WM and may be extended toward the top surface U-WM. The second side surface SS2a may be extended from the first side surface SS1a in a direction parallel to the top surface U-WM. The third side surface SS3 may be extended from the second side surface SS2a toward the top surface U-WM.

The light source LS may be disposed to face the first side surface SS1a and the second side surface SS2a. The additional light-blocking layer BBMAb may be disposed on the second side surface SS2a. Since the window WMb is processed to have a rectangular portion, it may be possible to secure a room for the light source LS and thereby to reduce a difficulty in a process of fabricating the display device DD.

According to an embodiment of the disclosure, light, which is emitted from a light source to obtain biometric data, may be incident into a window. Light, which is incident to the window, may propagate by total reflection. The window may have a structure for improving light receiving efficiency. The improvement of the light receiving efficiency may improve biometric-data-recognition sensitivity of a display device. In addition, since the window is provided as an optical system allowing for the total reflection, it may be possible to prevent a width of a light-blocking region of the display device from being increased and to omit an additional structure for shieling the light source.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device, comprising:
a window comprising a top surface, a bottom portion facing the top surface, and a side portion connecting the top surface to the bottom portion and the window comprising a transmission region and a light-blocking region;
a light-blocking layer disposed below the window and overlapping the light-blocking region in a plan view;
a light source spaced apart from the bottom portion in a direction in a plan view; and
a display panel disposed below the window, wherein the display panel comprises a light sensing device and comprises a display region overlapping the transmission region in a plan view.

2. The display device of claim 1, wherein the bottom portion comprises:
a first bottom surface parallel to the top surface; and
a second bottom surface which is connected to the first bottom surface and the side portion and is inclined with respect to the first bottom surface.

3. The display device of claim 2, wherein an angle between the first bottom surface and the second bottom surface is equal to or greater than about 165° and is smaller than or equal to about 175°.

4. The display device of claim 1, further comprising:
an optical layer disposed between the bottom portion of the window and the light-blocking layer,
wherein the optical layer overlaps an entire region of the light-blocking and transmission regions in a plan view.

5. The display device of claim 4, wherein a refractive index of the optical layer is lower than a refractive index of the window.

6. The display device of claim 5, wherein in case that the refractive index of the window is about 1.5, the refractive index of the optical layer is equal to or greater than about 1.3 and is equal to or smaller than about 1.4.

7. The display device of claim 1, wherein
the side portion comprises:
a first side surface connected to the bottom portion; and
a second side surface which is connected to the top surface and the first side surface and is inclined with respect to the first side surface, and
the light source faces the first side surface.

8. The display device of claim 7, wherein the second side surface overlaps the light source in a plan view.

9. The display device of claim 7, wherein an angle between the first side surface and the second side surface is equal to or greater than about 165° and is smaller than about 180°.

10. The display device of claim 7, further comprising:
an additional light-blocking layer disposed on the second side surface.

11. The display device of claim 1, further comprising:
a reflection part facing the side portion of the window,
wherein the light source is disposed between the reflection part and the side portion of the window.

12. The display device of claim 1, further comprising:
a first optical portion which is attached to a portion of the bottom portion and has a first inclined surface inclined with respect to the bottom portion; and
a second optical portion which is attached to the side portion and has a second inclined surface inclined with respect to the side portion.

13. The display device of claim 12, further comprising:
an adhesive member attaching each of the first optical portion and second optical portion to the window; and
an additional light-blocking layer disposed on the second inclined surface.

14. The display device of claim 12, wherein
an angle between the first inclined surface and the bottom portion is equal to or greater than about 165° and is equal to or smaller than about 175°, and
an angle between the second inclined surface and the side portion is equal to or greater than about 165° and is smaller than about 180°.

15. The display device of claim 12, wherein the light-blocking layer is disposed between the first optical portion and the window.

16. The display device of claim 1, wherein
the side portion comprises:
a first side surface which is connected to the bottom portion and is extended toward the top surface;
a second side surface which is extended from the first side surface in a direction parallel to the top surface; and
a third side surface which is extended from the second side surface toward the top surface,
wherein the light source is disposed to face the first side surface and the second side surface.

17. The display device of claim 16, further comprising:
an additional light-blocking layer disposed on the second side surface.

18. The display device of claim 1, wherein the light-blocking layer transmits infrared light and reflects visible light.

19. A display device, comprising:
a window comprising a top surface, a bottom portion facing the top surface, and a side portion connecting the top surface to the bottom portion and the window comprising a transmission region and a light-blocking region;
a light-blocking layer disposed below the window and overlapping the light-blocking region in a plan view;
a light source spaced apart from the bottom portion in a direction in a plan view; and
a display panel disposed below the window, wherein the display panel comprises a light sensing device and comprises a display region overlapping the transmission region in a plan view,
the bottom portion comprises:
a first bottom surface parallel to the top surface; and
a second bottom surface which is connected to the first bottom surface and the side portion and is inclined with respect to the first bottom surface, and
an angle between the first bottom surface and second bottom surface is equal to or greater than about 165° and is smaller than about 180°.

20. The display device of claim 19, further comprising:
an optical layer disposed between the bottom portion of the window and the light-blocking layer,
wherein the optical layer overlaps an entire region of the light-blocking and transmission regions in a plan view.
